(19) United States
(12) Patent Application Publication
(10) Pub. No.: US 2025/0308890 A1
(43) Pub. Date: Oct. 2, 2025

(54) METHOD FOR MANUFACTURING GAN HEMT DEVICE USING HOT SELF-SPLIT PROCESS

(71) Applicant: WAVELORD CO., LTD, Gyeonggi-do (KR)

(72) Inventor: June O SONG, Gyeonggi-do (KR)

(21) Appl. No.: 19/098,236

(22) Filed: Apr. 2, 2025

(30) Foreign Application Priority Data
Apr. 2, 2024 (KR) 10-2024-0044884
Jun. 18, 2024 (KR) 10-2024-0078587

(51) Int. Cl. H01L 21/02; C30B 25/18; C30B 29/40; H10D 30/01

(52) U.S. Cl. CPC H01L 21/0254; C30B 25/18; C30B 29/406; H01L 21/02378; H01L 21/0262; H10D 30/015

(57) ABSTRACT

Embodiments according to the present disclosure provide an epitaxy wafer for a GaN HEMT with enhanced electrical insulation, comprising: a growth substrate; a nucleation region grown on the growth substrate; a high-resistance region having electrically high resistance characteristics, which comprises a high-resistance unit region defined by a first region grown as a group III nitride semiconductor doped with carbon and a second region grown as a group III nitride semiconductor on the first region, which is provided on the nucleation region; and an active region including a channel region grown on the high-resistance region and a barrier region grown on the channel region.

### CROSS-REFERENCE TO RELATED APPLICATIONS

This application claims priority to Korean Patent Application Nos. 10-2024-0044884, filed on Apr. 2, 2024 and 10-2024-0078587 filed on Jun. 18, 2024. The entire disclosure of the applications identified in this paragraph is incorporated herein by reference.

### FIELD

The present invention relates to a method for manufacturing a GaN HEMT device, and more particularly, to a method for manufacturing a GaN HEMT device through a hot self-split process, which enables cost innovation while using an expensive SiC wafer as a seed substrate for GaN growth.

### BACKGROUND

GaN HEMT power semiconductors are a representative type of non-memory semiconductor.

Research on high-quality and high-performance power semiconductors is accelerating to enable stable operation even in high-voltage, high-current, and high-temperature environments.

Silicon (Si) growth substrates have been mainly used for the production of power semiconductors, but as demand for high-performance power semiconductors increases, research and development of power semiconductors using silicon carbide (SiC) or gallium nitride (GaN) as a growth substrate is expanding.

GaN HEMT power semiconductor devices are manufactured by growing them on heterogeneous material Si or SiC growth substrates due to the lack of commercialization of growth substrate manufacturing technology for homogeneous material gallium nitride (GaN) or aluminum nitride (AlN).

GaN HEMT power semiconductor devices grown on SiC growth substrates have similar lattice constants and coefficients of thermal expansion, so they have a low density of crystal defects including dislocations and uniform polarity, allowing for high-quality manufacturing. However, SiC growth substrates have a high cost issue.

GaN HEMT power semiconductor devices grown on relatively inexpensive Si growth substrates have problems such as large differences in lattice constants and thermal expansion coefficients, high crystal defect density, and lack of uniform polarity, making high-quality manufacturing impossible.

Therefore, it is necessary to develop technologies that can reduce high manufacturing costs while using a SiC growth substrate.

### SUMMARY

### Technical Problem

The present invention aims to provide a method for manufacturing a GaN HEMT device through a hot self-split process, which can reduce high manufacturing costs while using a SiC growth substrate.

### Technical Solution

Embodiments according to the present invention provide a method for manufacturing a GaN HEMT device through a hot self-split process, comprising: a seed substrate preparation step of preparing a SiC seed substrate; a device region growth step of epitaxially growing a device region on a growth surface of the seed substrate; a seed substrate modification step of forming a modification layer formed in the seed substrate as a surface parallel to the growth surface by irradiating a stealth laser into the seed substrate; an upper temporary substrate bonding step of bonding an upper surface of the device region and an upper temporary substrate via an upper bonding layer after the seed substrate modification step is performed; a seed region separation step of separating the seed substrate with the modification layer as a boundary to form a seed region on the device region side; a lower temporary substrate bonding step of bonding a lower temporary substrate to a lower surface of the seed region via a predetermined second bonding layer after the seed region separation step is performed; an upper temporary substrate removal step of removing the upper temporary substrate after the lower temporary substrate bonding step is performed; a lower temporary substrate removal step of removing the lower temporary substrate after the upper temporary substrate removal step is performed; and a fab process step of forming a metal electrode including a source, a drain, and a gate on the upper side of the device region between the device region growing step and the seed substrate modification step, or between the upper temporary substrate removal step and the lower temporary substrate removal step.

In embodiments of the present invention, the seed region separation step is performed during a cooling process after the upper temporary substrate bonding step is performed.

In embodiments of the present invention, in the seed substrate preparation step, the SiC seed substrate is prepared to a thickness of 1,000 μm or more.

In embodiments of the present invention, the seed substrate separated in the seed region separation step is reused as a growth substrate of the device region.

In embodiments according to the present invention, the device region is composed of group III nitrides, including GaN, AlGaN, AlN, or a combination thereof.

### Advantageous Effects

According to the present invention, a SiC seed substrate for a GaN HEMT power device can be separated into thin pieces without an external force and reused multiple times, so that the manufacturing cost of the GaN HEMT power device can be drastically reduced.

According to the present invention, since a SiC seed substrate can be reused, the device region can be grown on a thick SiC seed substrate, thereby improving the uniformity within the GaN HEMT power device wafer and reducing the defect rate.

### BRIEF DESCRIPTION OF DRAWINGS

FIGS. 1, 2, 3 and 4 are drawings showing the first, second, third and fourth embodiments of a method for manufacturing a GaN HEMT device through a hot self-split process according to the present invention, respectively.

### DETAILED DESCRIPTION

Hereinafter, embodiments of a method for manufacturing a GaN HEMT device through a hot self-split process according to the present invention will be described in detail with reference to the drawings.

The terms used below have been selected for convenience of explanation, and should be appropriately interpreted in a meaning that is consistent with the technical idea of the present invention without being limited to the dictionary meaning.

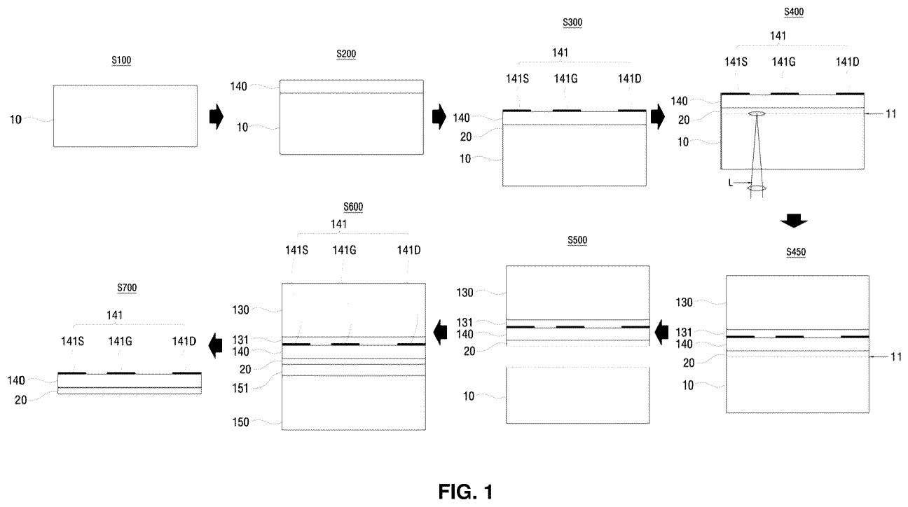

FIG. 1 is a drawing showing a first embodiment of a method for manufacturing a GaN HEMT device through a hot self-split process according to the present invention.

Referring to FIG. 1, the manufacturing method of the present embodiment comprises a seed substrate preparation step (S100), a device region growth step (S200), a fab process step (S300), a seed substrate modification step (S400), and a seed region separation step (S500).

In addition, the present embodiment further comprises an upper temporary substrate bonding step (S450) between the seed substrate modification step (S400) and the seed region separation step (S500), and comprises a lower temporary substrate bonding step (600) and a temporary substrate removal step (S700) after the seed region separation step (S500).

The temporary substrate removal step (S700) means the separation of the upper temporary substrate and the lower temporary substrate.

The seed substrate preparation step (S100) prepares the seed substrate (10) on which the device region (140) will be grown.

The material of the seed substrate (10) is SiC, and the seed substrate preferably has a thickness of 1,000 μm or more as the maximum thickness that the MOCVD process can be performed.

The seed substrate (10) preferably has a growth surface on which the device region (140) is grown, which is a Si polar surface.

The device region growth step (S200) forms the device region (140) on the seed substrate (10) by an epitaxial growth method.

The device region (140) is composed of group III nitrides, including GaN, AlGaN, AlN, or a combination thereof.

The fab process step (S300) forms a metal electrode (141) on the upper side of the device region (140).

The metal electrode (141) is a source electrode (141S) and a drain electrode (141D) deposited as an Ohmic contact, and a gate electrode (141G) deposited as a Schottkey contact.

The seed substrate modification step (S400) irradiates a stealth laser into the seed substrate (10) through the lower surface of the seed substrate (10) to form a modification layer (11) inside the seed substrate (10).

The modification layer (11) is formed as a surface parallel to the growth surface.

The stealth laser (L) is a laser with a wavelength that can penetrate the seed substrate (10), and forms a focal point at a specific point inside the seed substrate (10).

Therefore, when the focal point of the stealth laser (L) moves along a specific plane and forms a scanning plane in the shape of a point, line, or lattice cell, a modification layer (11) is formed along the scanning plane.

The upper temporary substrate bonding step (S450) bonds the upper surface of the device region (140) and the upper temporary substrate (130) via the upper bonding layer (131).

The bonding of the upper temporary substrate (130) is for stable workability of the post-process.

The upper bonding layer (131) uses a material (polymer, resin, metal, etc.) that makes it easy to remove the upper temporary substrate (130), and bonding is performed at a temperature of 100 to 350° C. depending on the bonding material.

The seed region separation step (S500) is separated without external force during the cooling process from the bonding temperature of the upper temporary substrate bonding step (S450).

The upper temporary substrate bonding step (S450) provides stable workability, thereby reducing the manufacturing cost of GaN HEMT devices and contributing to improved yield.

Since the seed region (20) is separated with the modification layer (11) as the boundary after the upper temporary substrate (130) is bonded while the device region (140) is formed on the seed substrate (10), the possibility of damage to the device region (140) can be reduced.

In addition, since the seed region (20) is separated from the seed substrate (10) while the thick upper temporary substrate (130) is attached, it is possible to form a modification layer (11) so that the seed region (20) has a thin thickness.

In addition, the upper temporary substrate (130) provides structural stability for performing subsequent processes such as polishing, CMP, via hole, and wiring of the lower surface of the separated seed region (20).

Therefore, the upper temporary substrate (130) not only safely protects the device region (140), but also minimizes the thickness of the seed region (20), thereby reducing manufacturing costs.

In addition, the upper temporary substrate (130) maximizes the structural asymmetry on both sides with the modification layer (11) as the boundary. as a result, the hot self-split process is smoothly performed.

The seed region separation step (S500) separates the seed substrate (10) on the device region (140) side with the modification layer (11) as the boundary to form a seed region (20).

The seed region separation step (S500) generates thermal stress or mechanical stress in the modification layer (11) by having structural asymmetry including quantitative differences in thermal characteristics including thermal expansion coefficient or thickness differences on both sides bordering the modification layer (11).

Therefore, the seed substrate (10) is separated without any mechanical external force across the modification layer (11).

That is, due to the bonding temperature of the upper temporary substrate bonding step (S450), the two sides bordering the modification layer (11) have a difference in thermal expansion rate, and this difference becomes more evident due to the structural asymmetry. Thereafter, during the cooling process, they are separated without external force.

More specifically, with the modification layer (11) as the boundary, one side has a structure in which a seed region (20), a device region (140), and an upper temporary substrate (130) are laminated, and the other side has a seed substrate (10) having a thickness excluding the thickness of the seed region (20).

Therefore, due to structural differences, the effective thermal expansion coefficient and effective thermal conductivity on both sides of the modification layer (11) are different from each other.

This is the reason why the two sides with the modification layer (11) as the boundary have different thermal expansion rates, and acts as a factor for separation without external force with the modification layer (11) as the boundary.

In addition, the two sides with the modification layer (11) as the boundary have different thicknesses and materials. Therefore, the internal stress distribution of the two sides with the modification layer (11) as the boundary is different.

This generates mechanical stress at the boundary of the modification layer (11), and acts as another factor for separation without external force with the modification layer (11) as the boundary.

The lower temporary substrate bonding step (600) bonds the lower temporary substrate (150) to the lower surface of the seed region (20) via the second bonding layer (151) after the seed region separation step (S500) is performed.

In the temporary substrate removal step (S700), the upper temporary substrate (130) and the lower temporary substrate (150) are sequentially removed.

The upper temporary substrate (130) is configured for a hot self-split process.

The lower temporary substrate (150) is configured to minimize adverse effects on the seed region (20) and the device region (140) when the upper temporary substrate (130) is removed.

In addition, the lower temporary substrate (150) provides structural stability for processes such as passivation and heat treatment of the device region (140) after the upper temporary substrate (130) is removed.

Meanwhile, the separated seed substrate is reused for the growth of a new device region.

According to the present embodiment, since the consumption of the seed substrate (10) can be minimized by the hot self-split process, there is no cost burden even if a thick seed substrate (10) is used for the growth of the device region.

As the thickness of the seed substrate (10) is thicker, wafer bowing is minimized in a high-temperature process, so there is room to increase the growth temperature of the device region. Therefore, a high-quality device region (140) can be obtained by using a thick seed substrate (10).

According to this embodiment, the consumption of the disposable material, SiC seed substrate, can be minimized, and a thin seed region (20) can be easily obtained. At the same time, the quality of the device region can be maximized.

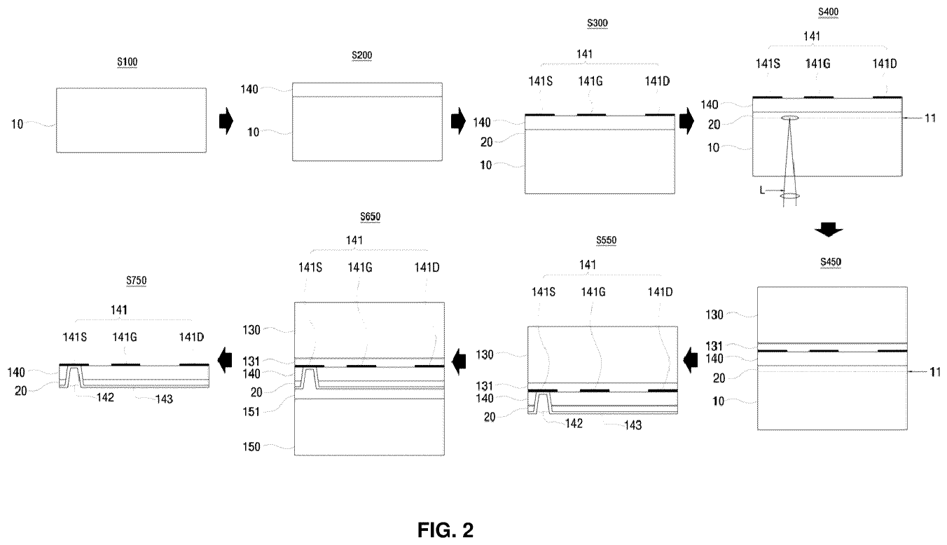

FIG. 2 is a drawing showing a second embodiment of a method for manufacturing a GaN HEMT device through a hot self-split process according to the present invention.

The manufacturing method of this embodiment differs from the first embodiment described above in that it further comprises a via hole and wiring process step (S550), and the rest is substantially the same.

Referring to FIG. 2, the via hole and wiring process step (S550) forms a via hole from the lower surface of the seed region (20) to the metal electrode (141) upwardly after the seed region separation step (S500) is performed, and forms a wiring (143) between a plurality of metal electrodes (141S) exposed downwardly through the via hole (142).

In the via hole and wiring process step (S550), the upper temporary substrate (130) provides rigidity to the seed region (20) and the device region (140), thereby providing the advantage of stability and excellent workability.

Meanwhile, in the present embodiment, the lower temporary substrate bonding step (S650) is performed after the via hole and wiring process step (550).

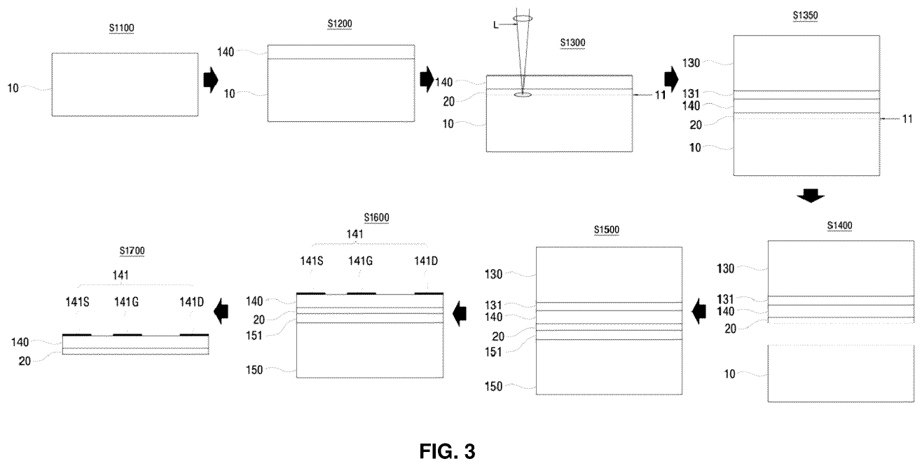

FIG. 3 is a drawing showing a third embodiment of a method for manufacturing a GaN HEMT device through a hot self-split process according to the present invention.

Referring to FIG. 3, the manufacturing method of the present embodiment comprises a seed substrate preparation step (S1100), a device region growth step (S1200), a seed substrate modification step (S1300), and a seed region separation step (S1400).

In addition, an upper temporary substrate bonding step (S1350) is performed between the seed substrate modification step (S1300) and the seed region separation step (S1400), and a lower temporary substrate bonding step (S1500) and a temporary substrate removal step (S1600, S1700) are performed after the seed region separation step (S1400).

Since each of the above-described steps is substantially the same as that of the first embodiment, the description thereof will be replaced with the description of the first embodiment.

The temporary substrate removal step (S1600, S1700) removes the upper temporary substrate (130) and then removes the lower temporary substrate (150).

The present embodiment has a difference in that a fab process step of forming a metal electrode (141) including a source, a drain, and a gate on the upper side of the device region (140) is performed between the upper temporary substrate removal step (S1600) and the lower temporary substrate removal step (S1700).

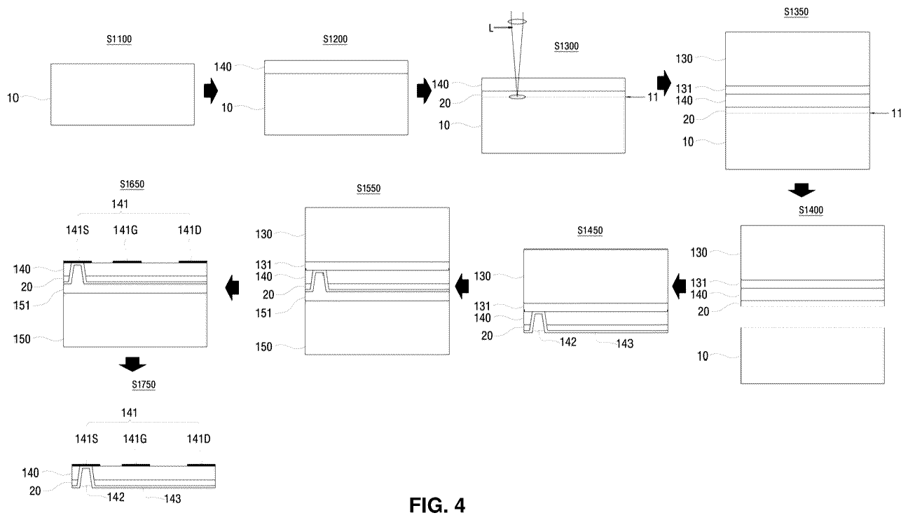

FIG. 4 is a drawing showing a fourth embodiment of a method for manufacturing a GaN HEMT device through a hot self-split process according to the present invention.

The manufacturing method of this embodiment differs from the third embodiment described above in that it comprises a via hole and wiring process step (S1450), and the rest is substantially the same.

Referring to FIG. 4, the via hole and wiring process step (S1450) forms a via hole from the lower surface of the seed region (20) to the upper side where a metal electrode (141) is to be formed, after the seed region separation step (1400) is performed, and forms a wiring (143) between a plurality of metal electrodes (141S) to be exposed downward through the via hole (142).

In the via hole and wiring process step (S1450), the upper temporary substrate (130) provides rigidity to the seed region (20) and the device region (140), thereby providing the advantage of stability and excellent workability.

The lower temporary substrate bonding step (S650) is performed after the via hole and wiring process step (S1450).

In the present embodiment, since the via hole and wiring process step (S1450) is performed before the fab process step, the wiring (143) is formed at the exposure location of the metal electrode (141S).

The fab process step is performed after the upper temporary substrate removal step (S1650) is performed.

What is claimed is:

1. A method for manufacturing a GaN HEMT device through a hot self-split process, comprising:
a seed substrate preparation step of preparing a SiC seed substrate;
a device region growth step of epitaxially growing a device region on a growth surface of the seed substrate;
a seed substrate modification step of forming a modification layer formed in the seed substrate as a surface parallel to the growth surface by irradiating a stealth laser into the seed substrate;
an upper temporary substrate bonding step of bonding an upper surface of the device region and an upper temporary substrate via an upper bonding layer after the seed substrate modification step is performed;
a seed region separation step of separating the seed substrate with the modification layer as a boundary during a cooling process after the upper temporary substrate bonding step to form a seed region on the device region side;
a lower temporary substrate bonding step of bonding a lower temporary substrate to a lower surface of the seed region via a predetermined second bonding layer after the seed region separation step is performed;
an upper temporary substrate removal step of removing the upper temporary substrate after the lower temporary substrate bonding step is performed;
a lower temporary substrate removal step of removing the lower temporary substrate after the upper temporary substrate removal step is performed; and
a fab process step of forming a metal electrode including a source, a drain, and a gate on the upper side of the device region between the device region growing step and the seed substrate modification step, or between the upper temporary substrate removal step and the lower temporary substrate removal step.

2. The method of claim 1, wherein the seed region separation step is performed without external force during the cooling process from the bonding temperature of the upper temporary substrate bonding step.

3. The method of claim 2, wherein the bonding temperature of the upper temporary substrate bonding step is 100 to 350° C.

4. The method of claim 2, wherein in the seed region separation step, both sides of the modified layer as a boundary have structural asymmetry and a quantitative difference in thermal characteristics, thereby being separated without an external force by thermal stress or mechanical stress formed in the modified layer.

5. The method of claim 2, further comprises a via-hole and wiring process step of forming a via-hole from the lower surface of the seed region to the metal electrode upward between the seed region separation step and the lower temporary substrate bonding step, and forming wiring between a plurality of the metal electrodes exposed downward through the via-hole.

6. The method of claim 1, wherein in the seed substrate preparation step, the SiC seed substrate is prepared to a thickness of 1,000 μm or more as the maximum thickness that the MOCVD process can be performed.

7. The method of claim 1, wherein the seed substrate separated in the seed region separation step is reused as a growth substrate of the device region.

8. The method of claim 1, wherein a growth surface of the seed substrate is a Si polar surface.
